(19) United States
(12) Patent Application Publication
(10) Pub. No.: US 2026/0205119 A1
(43) Pub. Date: Jul. 16, 2026

(54) ELECTRICAL MULTI-WAY SWITCH

(71) Applicant: KOSTAL Automobil Elektrik GmbH & Co. KG, Lüdenscheid (DE)

(72) Inventors: Tobias Hafner, Dortmund (DE); Kristofer Erlenkämper, Lünen (DE); Marco Ludwig, Hamm (DE); Kristian Lanzon, Sprockhövel (DE)

(73) Assignee: KOSTAL Automobil Elektrik GmbH & Co. KG, Lüdenscheid (DE)

(21) Appl. No.: 19/566,696

(22) Filed: Mar. 13, 2026

Related U.S. Application Data
(63) Continuation of application No. PCT/EP2024/075867, filed on Sep. 17, 2024.

(30) Foreign Application Priority Data
Sep. 21, 2023 (DE) 102023125594.0

(51) Int. Cl. H03K 17/97; G05G 9/047

(52) U.S. Cl. CPC H03K 17/97; G05G 9/04785; G05G 2009/04729; G05G 2009/04755; G05G 2009/04766; G05G 2009/04777; H03K 2017/9713

(57) ABSTRACT

An electrical multi-way switch includes an actuating lever movable out of its neutral position and movable back into its neutral position when an actuating force is discontinued. A permanent magnet is fastened to the actuating lever in the area of a distal end of the actuating lever situated opposite an actuating handle of the actuating lever. The permanent magnet cooperates with a magnetic field-sensitive sensor configured to detect direction and extent of a movement of the actuating lever. The actuating lever is supported by an articulated joint on a housing inside which the sensor device is mounted, the distal end of the actuating lever is surrounded by an electrical coil, and by pulsed energization of the electrical coil a force pulse may be imparted to the permanent magnet, which results in a movement of the actuating lever that is perceptible by the operator as haptic feedback.

### CROSS-REFERENCE TO RELATED APPLICATIONS

This application is a continuation of International Application No. PCT/EP2024/075867, published in German, with an international filing date of Sep. 17, 2024, which claims priority to DE 10 2023 125 594.0, filed Sep. 21, 2023, the disclosures of which are hereby incorporated in their entirety by reference herein.

### TECHNICAL FIELD

The present invention relates to an electrical multi-way switch having an actuating lever, a permanent magnet, and a magnetic field-sensitive sensor device. The actuating lever is provided with an actuating handle. The actuating lever is movable out of its neutral position and moves back into the neutral position when an actuating force is discontinued. The actuating lever is movable in its axial direction and is swivelable about at least one axis extending perpendicular to the axial direction. A movement of the actuating lever that is perceptible by an operator as haptic feedback may be brought about. The permanent magnet is fastened to the actuating lever in the area of the distal end of the actuating lever situated opposite its actuating handle. The permanent magnet cooperating with the magnetic field-sensitive sensor device that is configured to detect the direction and the extent of a movement of the actuating lever.

### BACKGROUND

German Patent Application DE 198 59 698 A1 discloses such an electrical multi-way switch that is designed as a four-way switch module. The switch module has a housing with a housing upper part and a housing lower part, and an actuating lever that is movable out of its neutral position in four actuation directions. A reset device that includes a spring-loaded, displaceably supported pressure piece and a control cam cooperating therewith causes the actuating lever to be moved back into its neutral position when an actuating force is discontinued.

German Patent Specification DE 101 28 436 C1 (corresponds to U.S. Publication No. 2003/0006963) discloses an electrical multi-way switch having an actuating lever that is supported in a housing so that the actuating lever is swivelable about two orthogonal axes by means of an articulated joint that is designed as an elastic plastic molded part.

German Patent Application DE 10 2011 079 863 A1 (corresponds to U.S. Publication No. 2014/0150598) discloses an electrical multi-way switch having a lifting armature magnet and a lifting armature situated at the actuating lever. A movement of the actuating lever that is perceptible by the operator as haptic feedback may be brought about by the actuator.

### SUMMARY

An electrical multi-way switch according to embodiments of the present invention has the advantage over the prior art in that the electrical multi-way switch allows the same functionality, using much simpler and cost-effective means in a very compact design.

According to embodiments of the present invention, the advantage over the prior art is achieved in that the actuating lever is supported, by means of an articulated joint, on a housing inside which the magnetic field-sensitive sensor device is mounted, the distal end of the actuating lever is surrounded by an electrical coil, and by pulsed energization of the electrical coil a force pulse may be imparted to the permanent magnet, which brings about the movement of the actuating lever which is perceptible by the operator as haptic feedback.

Movability of the actuating lever in multiple degrees of freedom is achievable in a particularly simple manner by designing the articulated joint as an elastomeric molded part.

An advantage of the multi-way switch according to embodiments of the present invention is that by use of the actuating lever, only a relatively small mass must be moved, which in particular for an articulated joint that is designed as an elastomeric molded part, is also decoupled from the housing in terms of vibration. Thus, on the one hand, only a small quantity of energy is necessary for generating haptic feedback, and on the other hand, the haptic feedback is perceptible only at the actuating lever and not also at the housing, for example.

The magnetic field-sensitive sensor device may include an evaluation circuit that is configured, depending on the direction and magnitude of the detected movements of the actuating lever, to generate switching signals that are associated with the movements.

The magnetic field-sensitive sensor device may include a 3D Hall sensor that is advantageously mounted on a circuit carrier inside the housing in such a way that the 3D Hall sensor is situated directly opposite from the distal end of the actuating lever in its neutral position.

The electrical coil may be designed as a ring-shaped air coil and is mounted inside the housing in such a way that it surrounds the actuating lever in its neutral position, concentrically with respect to the axial direction of the actuating lever.

### BRIEF DESCRIPTION OF THE DRAWINGS

An electrical multi-way switch according to embodiments of the present invention is explained below with reference to the appended drawings, in which:

FIG. 1 illustrates a longitudinal cross section of an electrical multi-way switch in accordance with an embodiment of the present invention; and

FIG. 2 illustrates two isometric detailed views of the area of an axial support of the actuating lever on an elastomeric molded part.

### DETAILED DESCRIPTION

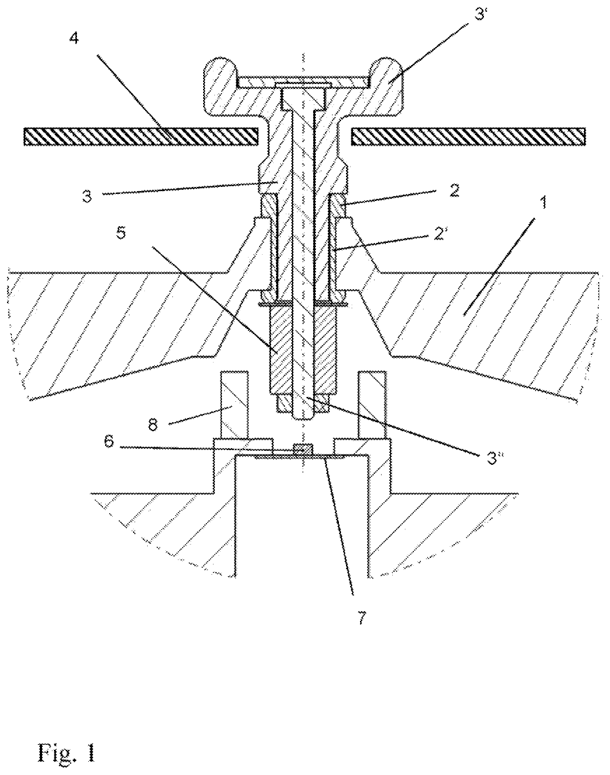

An electrical multi-way switch designed according to the present invention is shown in the longitudinal cross section in FIG. 1. The electrical multi-way switch includes a housing 1 and an actuating lever 3. Actuating lever 3 is fixed to housing 1. Actuating lever 3 includes an actuating handle 3′. Actuating handle 3′ is arranged outside housing 1. Actuating handle 3′ in the present case is designed as a finger rest for an operator's finger. Actuating handle 3′ here is surrounded by a control panel 4 which blocks a view of housing 1 thereunder. Actuating lever further includes a distal end 3″ that is opposite its actuating handle 3′.

Actuating lever 3 is supported on housing 1 by means of an articulated joint 2. Articulated joint 2 is designed as an elastomeric molded part 2. Actuating lever 3 is supported on housing 1 by elastomeric molded part 2 in such a way that from its neutral position actuating lever 3 is movable in its axial direction and is also swivelable about at least one axis extending perpendicular to the axial direction. When an actuating force is discontinued, actuating lever 3 automatically moves back into its neutral position due to the spring action of elastomeric molded part 2.

An axial movement of actuating lever 3 can thus take place as the result of a centrally exerted pressure on actuating handle 3, while swiveling of actuating lever 3 takes place due to pressure on the edge area of actuating handle 3′. The forces for the axial movement and for the swiveling of actuating lever 3 are adjustable via the design of elastomeric molded part 2.

The forces necessary for swiveling actuating lever 3 are determined essentially by the length and the wall thickness of a hollow cylindrical section 2′ of elastomeric molded part 2. Hollow cylindrical section 2′ of elastomeric molded part 2 fills the space between actuating lever 3 and the cylindrical borehole in the wall of housing 1.

In contrast, the pressure force necessary for the axial movement of actuating lever 3 may be adjusted in a particularly simple manner via the design of the support of actuating lever 3 on a collar-shaped section of elastomeric molded part 2 which surrounds the cylindrical borehole in the wall of housing 1.

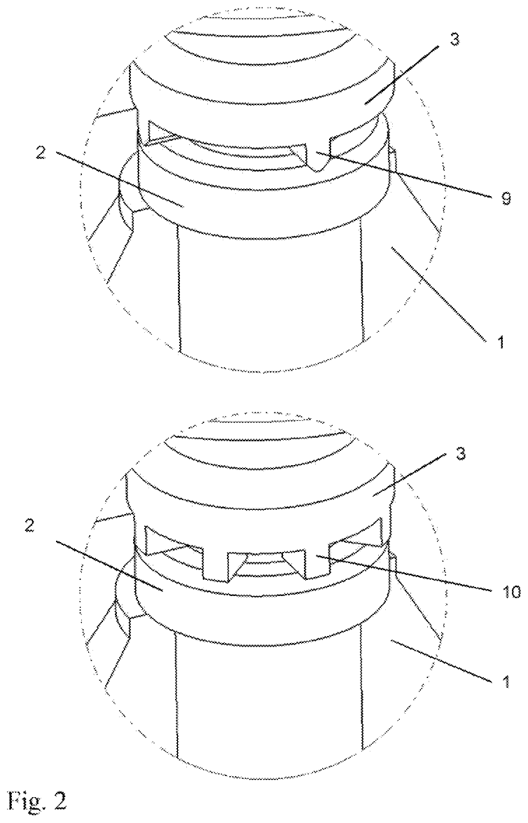

FIG. 2 shows by way of example two different geometries in which the axial supports of actuating lever 3 on elastomeric molded part 2 are formed in each case by ribs 9, 10 that are molded onto actuating lever 3. In the top illustration of FIG. 2, four ribs 9 which taper toward elastomeric molded part 2 are used which require relatively less pressure force for the axial movement of actuating lever 3 than the eight ribs 10 shown in the bottom illustration of FIG. 2, which in addition rest flush against elastomeric molded part 2.

The electrical multi-way switch further includes a permanent magnet 5. Permanent magnet 5 is fastened to distal end 3″ of actuating lever 3. In the embodiment shown here, permanent magnet 5 has a ring-shaped or hollow cylindrical design and thus encompasses an area of distal end 3″ of actuating lever 3. The magnetization direction of permanent magnet 5, i.e., its north-south alignment, extends in parallel to the axial direction of actuating lever 3.

The electrical multi-way switch further includes a magnetic field-sensitive sensor device 6. Magnetic field-sensitive sensor device 6 is mounted inside housing 1. In a first function, permanent magnet 5 is provided for cooperating with magnetic field-sensitive sensor device 6. Magnetic field-sensitive sensor device 6 is configured to detect the direction and the extent of a movement of actuating lever 3 out of its neutral position.

For this purpose, magnetic field-sensitive sensor device 6 includes a so-called 3D Hall sensor 6 with which the intensity and alignment of a magnetic field in space, and thus the position and orientation of a magnet that generates this magnetic field, in this case permanent magnet 5, may be detected. 3D Hall sensor 6 is mounted on a circuit carrier 7 inside housing 1 in such a way that 3D Hall sensor 6 is situated directly opposite from distal end 3″ of actuating lever 3 in the neutral position of actuating lever 3. As a further component of magnetic field-sensitive sensor device 6, an evaluation circuit may, for example, also be directly present on circuit carrier 7. The evaluation circuit, depending on the direction and magnitude of the detected movements of actuating lever 3, generates switching signals that are associated with these movements.

The electrical multi-way switch further includes an electrical coil 8. Electrical coil 8 surrounds distal end 3″ of actuating lever 3. Electrical coil 8 is designed as a ring-shaped air coil and is mounted inside housing 1 in such a way that it surrounds distal end 3″ of actuating lever 3 in its neutral position, concentrically with respect to the axial direction of actuating lever 3. By energizing electrical coil 8, a magnetic field may be generated which is aligned parallel or antiparallel to the magnetic field of permanent magnet 5 in the neutral position of actuating lever 3, depending on the current direction. By pulsed energization of electrical coil 8, a force pulse may be imparted to permanent magnet 5, which causes a likewise pulsed movement of actuating lever 3. An operator's finger resting on actuating handle 3′ in turn perceives this brief movement as a force pulse, so that haptic feedback to the operator may be generated by energizing electrical coil 8.

What is claimed is:

1. An electrical multi-way switch comprising:
a housing;
an articulated joint;
an actuating lever having an actuating handle and a distal end opposite to the actuating handle, the actuating lever being supported on the housing by the articulated joint such that in response to an actuating force on the actuating handle the actuating lever is movable out of a neutral position in an axial direction of the actuating lever and is swivelable about at least one axis extending perpendicular to the axial direction and in response to the actuating force on the actuating handle being discontinued the actuating lever is movable back into the neutral position due to a spring action of the articulated joint;
a magnetic field-sensitive sensor device mounted to the housing;
a permanent magnet fastened to the distal end of the actuating lever and encompassing a portion of the distal end of the actuating lever, the permanent magnet cooperating with the magnetic field-sensitive sensor device for the magnetic field-sensitive sensor device to detect direction and magnitude of movement of the actuating lever; and
an electrical coil mounted to the housing and surrounding the distal end of the actuating lever and the permanent magnet; and
wherein by pulsed energization of the electrical coil a force pulse may be imparted to the permanent magnet, which results in a movement of the actuating lever that is perceptible by an operator's finger resting on the actuating handle as haptic feedback whereby haptic feedback to the operator may be generated by energizing the electrical coil.

2. The electrical multi-way switch according to claim 1, wherein:
the articulated joint is an elastomeric molded part.

3. The electrical multi-way switch according to claim 1, wherein:
the magnetic field-sensitive sensor device includes an evaluation circuit configured to, depending on the direction and magnitude of movements of the actuating lever, generate switching signals that are associated with the movements.

4. The electrical multi-way switch according to claim 1, wherein:
the magnetic field-sensitive sensor device includes a 3D Hall sensor.

5. The electrical multi-way switch according to claim 4, wherein:
the 3D Hall sensor is mounted on a circuit carrier that is mounted inside the housing such that the 3D Hall sensor is situated directly opposite from the distal end of the actuating lever in the neutral position of the actuating lever.

6. The electrical multi-way switch according to claim 5, wherein:
the electrical coil is a ring-shaped air coil and is mounted inside the housing such that the electrical coil surrounds the actuating lever in the neutral position of the actuating lever concentrically with respect to the axial direction of the actuating lever.

7. The electrical multi-way switch according to claim 1, wherein:
a magnetization direction of the permanent magnet extends in parallel to the axial direction of the actuating lever.

8. The electrical multi-way switch according to claim 1, wherein:
the actuating handle is arranged outside the housing.

9. The electrical multi-way switch according to claim 1, wherein:
actuating forces for the axial movement and for the swiveling of the actuating lever are adjustable via the articulated joint.

10. The electrical multi-way switch according to claim 9, wherein:
the articulated joint includes a hollow cylindrical section which fills a space between the actuating lever and a cylindrical borehole in a wall of the housing; and
wherein actuating forces for swiveling the actuating lever are determined by a length and a wall thickness of the hollow cylindrical section of the articulated joint.

11. The electrical multi-way switch according to claim 10, wherein:
actuating forces for axial movement of the actuating lever are adjustable via the support of the actuating lever on a collar-shaped section of the articulated joint which surrounds the cylindrical borehole in the wall of the housing.

12. The electrical multi-way switch according to claim 1, wherein:
the actuating lever includes a plurality of ribs; and
the ribs taper toward the articulated joint and function as axial supports for the actuating lever to be supported on the housing by the articulated joint.

13. The electrical multi-way switch according to claim 1, wherein:
the actuating lever includes a plurality of ribs; and
the ribs rest flush on the articulated joint and function as axial supports for the actuating lever to be supported on the housing by the articulated joint.
